(19) United States
(12) Patent Application Publication
(10) Pub. No.: US 2009/0117371 A1
(43) Pub. Date: May 7, 2009

(54) WEATHER-RESISTANT LAYER SYSTEM

(75) Inventors: Hans Joachim Glaeser, Gummersbach (DE); Hansjoerg Weis, Hoexter (DE)

Correspondence Address: SCULLY SCOTT MURPHY & PRESSER, PC, 400 GARDEN CITY PLAZA, SUITE 300, GARDEN CITY, NY, 11530, US

(73) Assignee: INTERPANE ENTWICKLUNGS-UND BERATUNGSGESELLSCHAFT MBH & CO. KG, Lauenfoerde (DE)

(21) Appl. No.: 12/296,393

(22) PCT Filed: Apr. 5, 2007
(86) PCT No.: PCT/EP07/03112

§ 371 Date: Oct. 7, 2008

(30) Foreign Application Priority Data
Apr. 7, 2006 (DE) 10 2006 016 512.8

(51) Int. Cl. B32B 9/04; B32B 17/06; C23C 16/44; C23C 14/28; C23C 14/34; C23C 16/513

(52) U.S. Cl. 428/332; 428/432; 428/698; 428/701; 427/255.28; 427/595; 204/192.1; 427/569

(57) ABSTRACT

The present invention describes a layer system applied onto a transparent substrate, which layer system contains, embedded in functional layers, one or more blocker layers.

The present invention relates to a layer system applied to a transparent substrate for preventing external fogging and weather soiling on the outer surface of glazing.

The effects of weathering on the outer surface of glazing are corrosion, weather soiling and misting or frost deposition.

These days, weather soiling may be reduced considerably using a photocatalytic TiO₂ layer on the outer surface, such that the cleaning intervals for the glazing may be significantly extended. This is possible because the layer has a markedly enhanced self-cleaning effect on weathering. The basic principle of this effect is that, on the one hand, hydrocarbons adsorbed onto the TiO₂ layer from the external atmosphere and which hydrophobise the surface and thus increase soiling are broken down on only slight irradiation with UV light, to which end relatively weak solar radiation is sufficient on external exposure. A photocatalytic process accordingly takes place on the layer surface—hence the name “photocatalytic” TiO₂ layer.

On the other hand, at the same time the layer surface becomes so highly and above all durably water-wetting, i.e. ultrahydrophilic, on incident light radiation that rainwater spreads out thereon. In this way, weather soiling deposits are infiltrated, loosened from the surface and rinsed away. The loosening of dirt from a surface and subsequent rinsing away of the dissolved dirt, both here performed with water, is a wash-cleaning process. The long term stable spreading of the rainwater on this layer has the additional effect that raindrops on the surface are no longer visible when looking perpendicularly through the surface; panes of glass coated in this way thus remain largely clearly transparent over a large area even in rain.

Current commercial products with a photocatalytic TiO₂ layer are “Activ” made by Pilkington and the “Bioclean” made by SSG. The layer structure here comprises a double layer consisting of a blocker layer, which is applied directly onto the glass surface and is designed to prevent the diffusion of sodium ions out of the glass into the photocatalytic layer applied thereover, which would neutralise the photocatalytic effect because the sodium ions would destroy electrical charge carriers, which are formed in the TiO₂ layer on UV irradiation and which trigger the photocatalytic effect at the layer surface.

External fogging, the other effect of weathering, is a consequence of the emission of heat in particular skywards from the outer glazing surface. If insufficient heat then continues to flow from the internal space to the outer surface, as is the case in particular with modern insulating glasses with U_{g} values of≦1.5 W/m²K, the temperature of the outer surface drops, leading to external fogging, i.e. condensation or frost deposition, in the case of sufficiently high relative external atmospheric humidity as a result of the temperature falling below the dew point.

This may very largely be stopped by arranging layers which have an emissivity εₐ of≦0.2 on the outer surface of the glazing, these therefore very largely suppressing thermal radiation, to the extent that frost deposition can no longer occur and condensation arises only exceptionally under climatic conditions such as prevail in central and northern Europe. A weather-resistant SnO₂:F layer is currently in commercial use on float glass with an emissivity εₐ of˜0.17, i.e. Pilkington's K Glass. Test glazing has shown that, with this glass as the external pane and the layer arranged towards the exterior, any currently commercial glazing with a U_{g} value of 0.5 to 1.5 W/m²K may be kept free of frost deposits and also largely free of condensation in central and northern European climates.

Both the photocatalytic TiO₂ layer and the SnO₂F layer also result in a positive side effect: they cover the surface of the glass and thus at the same time prevent corrosion of the outer glazing surface due to weathering.

Patent application EP 1 254 870 A2 (Pilkington) describes a photocatalytically active TiOx layer on a substrate. It describes, inter alia, an Na diffusion barrier layer, preferably of SiOx, between substrate and TiOx.

Patent application WO 2004/034105 A1 (Glaverbel) describes a light-reflecting layer (for example Cr) or a light-reflecting substrate and a photocatalytically active layer thereover, such as TiOx, and optionally an intermediate layer, such as SiOx, together optionally with a thin (max. 5 nm, e.g. SiOx) scratch protection layer. The overall system has a reflectivity of 40-75%. The function of the intermediate layer is likewise indicated as an Na diffusion barrier layer. The invention is applied to automotive rear-view mirrors.

Patent DE 69611618 T2 (Saint Gobain) teaches applying a coating to a substrate, wherein, with the assistance of a mineral binder, partially crystalline TiOx particles are present in the coating in the form of an amorphous or partially crystallised oxide or oxide mixture. The patent describes providing at least one thin layer under the coating, which layer has an antistatic, thermal or optical function or serves as a barrier against the migration of alkali metals out from the substrate. In particular, the patent in Example 4 teaches that for example a directly adjacent conductive sublayer of SnO₂:F has a favourable influence on the catalytic action of the TiOx-containing layer located thereover.

It is therefore the object of the present invention to develop a method with which corrosion, weather soiling and condensation and frost deposition on the outer surface of glazing may be prevented.

This object has been achieved with the layer system according to claim 1 and a method of producing the layer system. The subclaims relate to advantageous further developments.

The present invention relates to a layer system applied to a transparent substrate, which layer system contains at least one or more blocker layers, which are embedded between a TCO or metal layer and a top layer consisting of a photocatalytic layer. According to the invention, an intermediate layer is explicitly required between the photocatalytically active layer and a conductive layer or a conductive sublayer system.

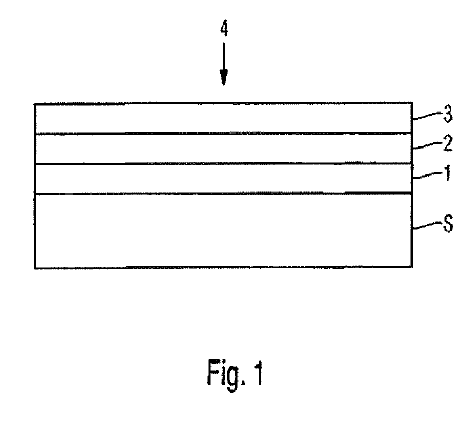

FIG. 1 shows an example of a multilayer structure of the layer combination according to the invention.

As is clear from FIG. 1, the layer system 4 comprises a plurality of layers, wherein at least one or more blocker layers 2 are provided. In one embodiment of the present invention, the layer system 4 includes, arranged on the transparent substrate S, a blocker layer 2, which is embedded between a TCO or metal layer 1 and a top layer comprising a photocatalytic layer 3.

According to the invention, the blocker layer prevents formation of the space-charge region. The blocker layer is distinguished by the following characteristics:

a) it has a lower electron affinity (W_{vac}-E_{c}) than the directly adjacent materials;

b) it has a larger band gap E_{g} between conduction and valence band than that of the photocatalytically active layer;

c) it has a layer thickness suitable for largely stopping the tunnelling of electrons out of the TCO into the photocatalytic layer and

d) it displays negligible absorption by lattice and ion vibration in the infrared range.

The following investigation was performed during development of the layer system.

A layer combination with a low-emitting base layer on a flat glass pane, for example made from a commercial TCO (transparent conductive oxide) with a surface resistivity R_{□}<20 Ω, was produced with a photocatalytic, i.e. polycrystalline photocatalytic layer, with a primarily anatase structure deposited thereover. It was, however, found that, when these two layers are combined, the photocatalytic property of the polycrystalline layer is lost. The same effect also arises when the photocatalytic layer is applied directly to a sheet of metal. The layer with a primarily anatase structure obviously only displays the photocatalytic action when it is applied to an insulator, for example to flat glass.

The cause of this phenomenon is that the layer combination of a TCO (or indeed a metal as substrate) and the photocatalytic TiO₂ layer located thereover leads to a heterogeneous pn-junction, i.e. the electrons from the TCO layer (or the metal surface) diffuse into the photocatalytic layer, wherein they leave behind at the TCO/photocatalytic layer boundary surface, facing towards the TCO, a positively charged space-charge region formed of the doping ions of the TCO (or the metal lattice ions). On irradiation with UV light, on the other hand, electron/hole pairs are formed in the photocatalytic layer, which pairs normally diffuse jointly to the layer surface and there trigger the photocatalytic reaction on the basis of a redox reaction. However, the electrons of this charge carrier pair formed by UV irradiation are extracted by the space-charge region; they are thus absent during the redox reaction at the surface of the photocatalytic layer, such that this can no longer take place.

According to a preferred embodiment of the present invention, the TCO layer 1 is formed of SnO₂:F, In₂O₃:Sn, ZnO:Al or ZnO:Sb and mixtures thereof. Preferably, the TCO layer 1 has a layer thickness of between 100 nm and 1000 nm, layer thicknesses of between 150 nm and 800 nm being preferred, wherein layer thicknesses of between 200 nm and 600 nm are particularly preferred.

Alternatively, this layer may be a metal layer, which is formed of a layer system based on Au or Ag, which is often also used as layers providing protection against heat and sun in the case of architectural or vehicle glazing.

The metal layer may advantageously contain further alloy metals. In a further embodiment of the present invention, one or more of the following alloy partners Ni, Pd, Pt, Th, Cr, Cu, Zr, Al or Ti are admixed with the metal layer 1. The metal layer 1 should preferably have a thickness of between 5 nm and 25 nm, with a preferred layer thickness of between 7 nm and 20 nm and a particularly preferred layer thickness of between 8 nm and 18 nm.

It has proven advantageous for the metal layer 1 in the layer system according to the invention to be embedded in at least one transparent lower antireflection layer and at least one upper antireflection layer. Said layers are here conventional antireflection layers.

In a further preferred embodiment of the layer system according to the invention, the photocatalytically active layer 3 is formed of TiOx, wherein x is in the range between 1.8 and 2.2. In practice it has proven favourable for the TiOx to be present at least partially in crystalline form as rutile or anatase. In a more preferred embodiment of the present invention, the TiOx is present as anatase.

It is particularly advantageous for the layer system according to the invention to comprise a photocatalytically active layer 3 of TiOx, which is doped with an element which lowers the band gap of the TiOx. Examples of these elements are Fe, V, Nb, Cr, Al, Zn, Sn, Ce, Cu, Ta, Bi, elements from the group of lanthanoids, Ni, Co, Mo and/or W.

In practice, it has proven advantageous for the photocatalytically active layer 3 to have a layer thickness of between 2 nm and 15 nm. Preferably, the layer thickness is between 5 nm and 120 nm, particularly preferably between 10 nm and 80 nm.

The blocker layer 2 in the layer system 4 according to the invention is preferably composed of oxides of Zr, Al, Si, Hf, Nb, Ta, Mg, Zn, Y, Sn or mixtures thereof or of nitrides and oxynitrides of Al or Si or mixtures thereof or of SiOxNyCz. In a more preferred embodiment, the blocker layer 2 is formed of oxides of Zr, Nb, Zn, Al, Si and mixtures thereof.

The blocker layer 2 may be present as an individual layer, wherein, depending on the intended application, it may be favourable to provide two or more of these blocker layers.

Preferably, the blocker layer 2 has a thickness of between 5 and 300 nm, particularly preferably of between 5 and 50 nm.

FIG. 1 shows an example of a layer system according to the invention applied to a transparent substrate. On the substrate S there is located a TCO or metal layer 1. The blocker layer 2 is provided over this layer 1. On the blocker layer 2 there is located the top layer comprising a photocatalytic layer 3.

The layer system according to the invention has an emissivity of preferably less than εₙ≦0.50. It is more preferable for the emissivity of the layer system to be less than εₙ≦0.20, in particular the emissivity of the layer system is less than εₙ≦0.15.

The layer system according to the invention is distinguished by excellent transmittance, the layer system with the associated substrate S preferably having a transmittance of at least 60%. More preferably, transmittance amounts to at least 70%, in particular it amounts to 80%.

In principle, any substrate may be used in the layer system according to the invention provided it is ensured that said substrate is highly transparent. Preferably the substrate S consists of glass or a transparent plastic. As a rule, glass or plastic are present in the form of panes. The layer system according to the present invention may advantageously be such that it is arranged in combination with at least one further transparent substrate and at least one spacer disposed therebetween, wherein the layer system faces the outside.

In one embodiment of the present invention, the layer system 4 is such that at least one diffusion barrier layer acting as a barrier against sodium diffusion is applied between substrate S and the TCO or metal layer 1, the thickness of which diffusion barrier layer is between 5 nm and 150 nm. An Na diffusion barrier layer suitable for the present invention consists of SiOₓ or SiN_{y}, wherein the Na diffusion barrier layer consists of SiOₓ or SiN_{y}, wherein 1.7<x<2.1 and 1.1<y<1.4 applies.

An example of a preferred layer system 4 in the present invention is one in which the blocker layer 2 is formed on the TCO or metal layer 1 by ZrOₓ and the photocatalytically active layer 3 is based on TiOₓ.

The layer system according to the invention may be produced using conventional methods by application onto the substrate. Examples of producing the layer system according to the invention are a CVD method, sputtering and/or microwave coating. Which method or which combination of methods should be applied depends on the range of knowledge of the relevant person skilled in the art.

Optionally, the method of the invention may be performed as a plasma-assisted CVD method.

In one embodiment of the method according to the invention, the layer system is produced by applying at least one of layers 1 or 3 to a heated substrate, the temperature of which amounts to at least 100° C. and at most 500° C. on deposition, wherein a temperature of at least 130° C. is preferred and a temperature of at least 170° C. is particularly preferred.

In a further preferred embodiment of the method according to the invention, after at least one deposition step for layers 1 to 3, the layer is subjected to heat treatment at between 200° C. and 600° C. for a period of between 3 minutes and 330 minutes, wherein heat treatment at between 250° C. and 350° C. for a period of 120 minutes to 270 minutes is preferred.

Alternatively, the method may also be performed more favourably in such a way that, after at least one deposition step for depositing layers 1 to 3, the layer is subjected to heat treatment at between 600° C. and 700° C. for a period of between 2 minutes and 10 minutes, wherein heat treatment at between 620° C. and 650° C. for a period of 2 to 6 minutes is preferred.

The present invention is now explained in more detail with reference to an example of embodiment.

A blocker layer in the form of a 20 nm thick sputtered SiOx layer is inserted between a commercial TCO layer (for example K glass made by Pilkington) and a photocatalytically active layer deposited thereover. A photocatalytic effect is obtained. The thickness of the photocatalytically active TiOx layer amounts to approx. 30 nm.

1. A layer system (4) applied to a transparent substrate (S), which layer system (4) contains at least one or more blocker layers (2), which are embedded between a TCO or metal layer (1) and a top layer comprising a photocatalytic layer (3).

2. A layer system according to claim 1, characterised in that
the TCO layer (1) is formed of SnO₂:F, In₂0₃:Sn, ZnO:Al or ZnO:Sb and mixtures thereof.

3. A layer system according to claim 2, characterised in that
the TCO layer (1) has a layer thickness of between 100 nm and 1000 nm, preferably between 150 nm and 800 nm and particularly preferably between 200 nm and 600 nm.

4. A layer system according to claim 1, characterised in that
the metal layer (1) is formed of a layer system based on Au or Ag.

5. A layer system according to claim 4, characterised in that
one or more of the following alloy partners Ni, Pd, Pt, Th, Cr, Cu, Zr, Al or Ti are admixed with the metal layer (1).

6. A layer system according to claim 4 and/or 5, characterised in that
the metal layer (1) has a thickness of between 5 nm and 25 nm, preferably between 7 nm and 20 nm and particularly preferably between 8 nm and 18 nm.

7. A layer system according to claims 4, 5 and/or 6, characterised in that
the metal layer (1) is embedded into at least one transparent lower antireflection layer and at least one upper antireflection layer.

8. A layer system according to at least one of claims 1 to 7, characterised in that
the photocatalytically active layer (3) consists of TiOₓ, wherein x is in the range between 1.8 and 2.2.

9. A layer system according to claim 8, characterised in that
the TiOₓ is present at least partially in crystalline form as rutile or anatase.

10. A layer system according to claim 9, characterised in that
the TiOₓ is present as anatase.

11. A layer system according to claims 8, 9 and/or 10, characterised in that
the photocatalytically active layer of TiOₓ is doped with an element which lowers the band gap of the TiOₓ.

12. A layer system according to claim 11, characterised in that
the element is selected from Fe, V, Nb, Cr, Al, Zn, Sn, Ce, Cu, Ta, Bi, elements from the group of lanthanoids, Ni, Co, Mo and/or W.

13. A layer system according to at least one of claims 8 to 12, characterised in that
the photocatalytically active layer (3) has a layer thickness of between 2 nm and 150 nm, preferably between 5 nm and 120 nm and particularly preferably between 10 nm and 80 nm.

14. A layer system according to at least one of the preceding claims, characterized in that
the blocker layer (2) is composed of oxides of Zr, Al, Si, Hf, Nb, Ta, Mg, Zn, Y, Sn or mixtures thereof or of nitrides or oxynitrides of Al or Si or mixtures thereof or of SiOxNyCz.

15. A layer system according to claim 14, characterised in that
the blocker layer (2) is formed of oxides of Zr, Nb, Zn, Al, Si and mixtures thereof.

16. A layer system according to at least one of the preceding claims, characterised in that
the blocker layer (2) has a thickness of between 5 and 300 nm, preferably of 5 to 50 nm.

17. A layer system according to at least one of the preceding claims, characterized in that
the emissivity of the layer system is less than εₙ≦0.50.

18. A layer system according to claim 17, characterised in that
the emissivity of the layer system is less than εₙ≦0.20.

19. A layer system according to claim 18, characterized in that
the emissivity of the layer system is less than εₙ≦0.15.

20. A layer system according to at least one of the preceding claims, characterized in that,
with the associated substrate (S), it has a transmittance of at least 60%.

21. A layer system according to claim 20, characterized in that
that transmittance amounts to at least 70%.

22. A layer system according to claim 21, characterized in that
that transmittance amounts to at least 80%.

23. A layer system according to at least one of the preceding claims, characterised in that
the substrate (S) consists of glass or a transparent plastic.

24. A layer system according to at least one of the preceding claims, characterised in that
at least one diffusion barrier layer acting as a barrier against sodium diffusion is applied between substrate (S) and TCO or metal layer (1), the thickness of which diffusion barrier layer is between 5 nm and 150 nm.

25. A layer system according to claim 24, characterised in that
the Na diffusion barrier layer consists of SiOₓ or SiN_{y}, wherein 1.7<x<2.1 and 1.1<y<1.4 applies.

26. A layer system according to at least one of the preceding claims, characterized in that,
on the TCO or metal layer (1), the blocker layer (2) is formed by ZrOx and the photocatalytically active layer (3) is based on TiOx.

27. A layer system (4) according to at least one of the preceding claims in combination with at least one further transparent substrate and at least one spacer disposed therebetween, wherein the layer system faces the outside.

28. A method of producing a layer system according to at least one of claims 1 to 27 using a CVD method, sputtering and/or microwave coating.

29. A method according to claim 28, characterised in that the CVD method is performed with plasma assistance.

30. A method according to at least one of claims 28 to 29, characterised in that
at least one of the layers (1) or (3) is applied to a heated substrate (S), whose temperature on deposition amounts to at least 100° C. and at most 500° C., preferably amounts to at least 130° C. and particularly preferably amounts to at least 170° C.

31. A method according to at least one of claims 28 to 30, characterised in that,
after at least one deposition step for layers (1) to (3), the layer is subjected to heat treatment, which is performed at between 200° C. and 600° C. and lasts for between 3 minutes and 330 minutes, preferably between 250° C. and 350° C. and between 120 minutes and 270 minutes.

32. A method according to one of claims 28 to 30, characterised in that,
after at least one deposition step for the deposition of layers (1) to (3), the layer is subjected to heat treatment, which is performed at between 600° C. and 700° C. and lasts for between 2 minutes and 10 minutes, preferably between 620° C. and 650° C. and between 2 and 6 minutes.
